(19) United States
(12) Patent Application Publication
(10) Pub. No.: US 2018/0192507 A1
(43) Pub. Date: Jul. 5, 2018

(54) CIRCUIT SUPPORT FOR AN ELECTRONIC CIRCUIT, AND METHOD FOR MANUFACTURING A CIRCUIT SUPPORT OF SAID TYPE

(71) Applicant: OSRAM GmbH, Munich (DE)

(72) Inventors: Michael Schöwel, Wittislingen (DE); Peter Helbig, Sontheim an der Brenz (DE); Jozsef Szekely, Gannertshofen (DE); Sven Seifritz, Herbrechtingen (DE)

(21) Appl. No.: 15/736,802

(22) PCT Filed: May 18, 2016
(86) PCT No.: PCT/EP2016/061091

§ 371 Date: Dec. 15, 2017

(30) Foreign Application Priority Data
Jun. 30, 2015 (DE) 10 2015 212 169.0

(51) Int. Cl. H05K 1/02; H05K 1/18; H05K 3/02; H05K 3/46; H05K 3/00; F21S 41/19

(52) U.S. Cl. CPC H05K 1/0204; H05K 1/181; H05K 3/02; H05K 3/4644; H05K 3/0014; H05K 2201/10113; H05K 2201/0104; H05K 2201/068; H05K 2201/10106; H05K 2201/2036; F21S 41/192

(57) ABSTRACT

A circuit support for an electronic circuit may include at least one conductor track, a first insulation material with which the at least one conductor track is encapsulated by injection molding so as to form an insulating matrix and so as to leave open at least one first region for the connection of at least one electronic component of the electronic circuit, and a heat sink. The conductor track is encapsulated by injection molding with the first insulation material in such a way that the insulating matrix furthermore leaves open at least one second region which is arranged between the conductor track and the heat sink. The circuit support may further include a large number of spacers which are designed and arranged in order to set a height of the second region. The circuit support may further include a second insulation material with which the second region is filled.

The present invention relates to a circuit support for an electronic circuit, including at least one conductor track, a first insulation material with which the at least one conductor track is encapsulated by injection molding so as to form an insulating matrix and so as to leave open at least one first region for the connection of at least one electronic component of the electronic circuit, and also a heat sink. Said invention furthermore relates to a method for manufacturing a circuit support for an electronic circuit, which method includes the following steps: producing at least one conductor track from a starting material by removing unnecessary material, encapsulating the at least one conductor track by injection molding using a first insulation material so as to form an insulating matrix, wherein the encapsulation by injection molding is performed in such a way that at least one first region of the at least one conductor track is left open for the connection of at least one electronic component of the electronic circuit, and also providing a heat sink.

The problem addressed by the present invention is that of providing a circuit support concept in which a thermally optimized connection of electronic components, for example LED chips, SMD components, electrical components, to an electrically insulated or zero-potential heat sink arrangement is possible within a given installation space.

In the text which follows, the same reference symbols are used for identical and identically acting components. For reasons of clarity, these reference symbols are introduced only once.

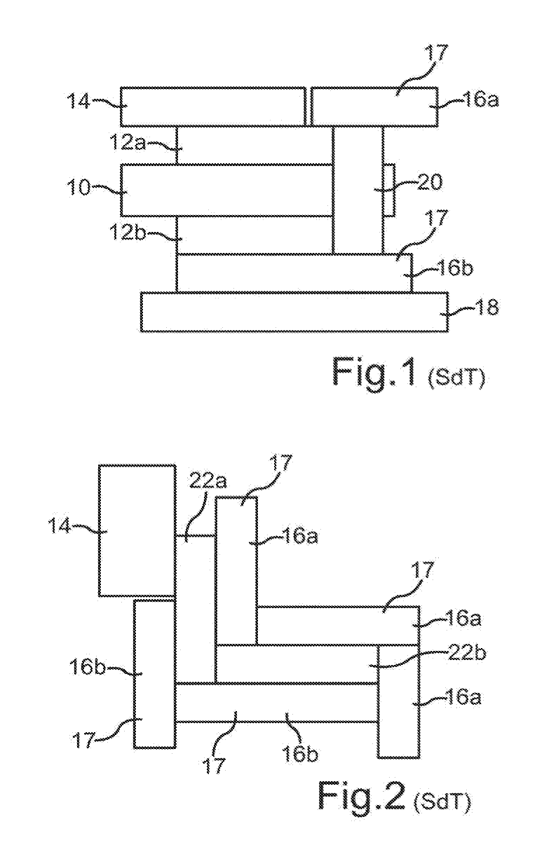

Several concepts are known from the prior art in order to achieve this objective: in this connection, FIG. 1 shows the cross section through a design taking as its example the use of a printed circuit board. The printed circuit board may be, for example, an FR4 printed circuit board, a metal-core printed circuit board or an A60 retrofit-type printed circuit board. In this case, the printed circuit board material 10 constitutes a main support which is electrically insulated and to which the conductor tracks 12a, 12b are applied, on both sides in the example shown in FIG. 1. The upper conductor track 12a serves to support the electronic components 14, for example the LED chips, SMD components and electrical components already mentioned above. The lower conductor track 12b serves, in particular, to carry away heat, which has been produced by the electronic components 14, to a heat sink 18.

The conductor tracks 12a, 12b are applied to the printed circuit board material 10 by means of a deposition or etching process. The surface of the printed circuit board material 10 constitutes an insulator. The conductor tracks 12a, 12b are encapsulated by injection molding using an insulating material 17, in particular composed of plastic, in order to firstly provide electrical insulation and secondly prevent said conductor tracks being torn off owing to different coefficients of thermal expansion when a connection between the conductor track 12b and the heat sink 18 is heated up. The cured insulation material 17 forms a matrix 16a, 16b.

Application of the insulating material 17 is costly in respect of process engineering since, for example for the purpose of electrical insulation, so-called spacers have to be provided in the material 17, said spacers being required in order to ensure electrical insulation. Different layer thicknesses of the insulation material 17 lead to undesired fluctuations in the dissipation of heat. In addition, the ratio of length of the conductor track 12b to the area of contact with the heat sink (by means of the insulation layer 16b) is important in respect of the dissipation of heat. In order to ensure good dissipation of heat, the conductor tracks 12a, 12b are therefore made relatively long perpendicular to the plane of the drawing, this meaning that the installation space which is required for a circuit support of this kind is undesirably relatively large.

In order to transfer the heat input from the components 14 to the conductor track 12a from said conductor track 12a to the conductor track 12b, so-called thermal vias 20 (electrically lined plated through-holes) are provided, these being complex and therefore expensive to manufacture.

If metal-core printed circuit boards are used as printed circuit board 10, said metal-core printed circuit boards have to be melted or welded onto the conductor track 12b, for example by laser transmission welding, for the purpose of transferring heat from the conductor track 12a to the conductor track 12b. Owing to the required dielectric properties and/or processability, the choice of material for the printed circuit board material 10 is limited, as is the thickness of the heat sink 18.

In summary, the dissipation capacity of the components 14 through the thin vias 20 and thin conductor tracks 12a, 12b, which usually have a layer thickness of approximately 35 μm, is considerably limited. This concept is furthermore adversely affected by a fluctuating thickness of the insulation layers 16a, 16b and is expensive and thermally limited.

The insulation layers 16a, 16b are relatively thick, and typically should be designed with a thickness of 0.2 to 0.3 mm, since otherwise the insulation could be locally broken if the relatively flexible printed circuit board 10 bends. In particular, the insulation layer 16b should therefore be designed to be relatively thick since the printed circuit board expands in a different manner to the heat sink 18 upon heating. The insulation layer 16b is sheared owing to these different coefficients of expansion. A minimum thickness should be provided in order to prevent the insulation layer 16b from being torn by this shearing. It is disadvantageous that the shearing angle is very large since the surface of the printed circuit board 10 is not metallic, whereas the surface of the heat sink 18 is metallic.

FIG. 2 shows a concept in which so-called lead frames, that is to say solid circuit supports which are encapsulated by injection molding, are used. The term lead frame is intended to be understood to mean, in particular, a solderable metal lead support in the form of a frame or comb for mechanically manufacturing semiconductor chips or other electronic components. The individual contacts, the so-called leads, are still connected to one another, and the frames of the individual products are likewise connected to one another and are supplied in rolled-up form. In addition, the term lead frame also identifies the form of the microchips which are produced using lead frames, that is to say the forms with protruding connections.

Lead frames are mounted on an insulating support or in a housing. If the contacts are mechanically fixed, as by the plastic matrix 16a, 16b in the present case, they can be separated from one another. Lead frames are punched, but can also be cut by laser.

In particular, the circuit support can be manufactured from a strip or a plate with material being removed, for example by a jet of water or laser, or without material being removed, for example by punching, and is made into a logic circuit, which is kept in form by means of the electrically insulating matrix 16a, 16b, by encapsulation by injection molding with the insulation material 17 for forming the matrix 16a, 16b and mechanical separation of the electrical contacts. The rigidity can be further increased by way of ribs.

In this case, the conductor tracks 22a, 22b are inherently rigid, that is to say they are self-supporting. The conductor tracks 22a, 22b are, for example, as mentioned, manufactured from a metal sheet using a punching process. In the circuit concept illustrated in FIG. 2, the conductor tracks 22a, 22b run at a perpendicular angle in relation to one another, this providing the advantage that the width of a circuit support of this kind, that is to say the extent in the plane of the drawing from left to right, can be reduced at the expense of the height, so that the volume of a circuit support formed with said conductor tracks can have an edge length which is as low as possible.

The lead frame is encapsulated by injection molding with the insulation material 17, in particular composed of plastic, so as to form the matrix 16a, 16b. After the encapsulation by injection molding, the leads, which are connected to one another by separating webs which are formed in the punching process for example, can be electrically isolated. The encapsulation by injection molding with the insulation material 17 is performed using an upper punch and a lower punch.

The lead frame material is used both for the conductor tracks 22a, 22b and also as a cooling lug. In this case, sheet metal strips of the starting material are, for example, folded since the dissipation of heat is proportional to the surface. As a result, the claimed installation space for a heat sink which is formed in this way can be kept relatively low. Since the dissipation of heat by means of cooling lugs which are formed in this way is relatively limited, additional dissipation of heat from the conductor tracks 22a, 22b through the insulation layers 16a, 16b is required and therefore said insulation layers should be manufactured from a highly thermally conductive and therefore unfortunately expensive material. Moreover, considerable material losses are produced owing to the processing in the case of this concept, that is to say the punched-out material which is not required has a negative effect on costs.

The thickness of the insulation layers 16a, 16b is between 0.2 and 0.3 mm in this case too.

The object of the present invention is therefore to develop a circuit support of the kind outlined in the introductory part in such a way that improved dissipation of heat is possible, so that the required installation space can be further reduced in comparison to the concepts known from the prior art and/or electronic components of higher power classes can be operated in a given installation space. A further object of the invention is to provide a method for manufacturing a corresponding circuit support.

The objects are achieved by a circuit support having the features of patent claim 1 and also by a method having the features of patent claim 11.

The present invention is based on the finding that the above object can be achieved by the insulation material which is provided between the conductor track and the heat sink firstly being provided as a very thin layer and secondly being selected to have very good thermal conduction properties. In order to precisely set the thickness of this insulation layer, a circuit support according to the invention includes correspondingly designed and arranged spacers. Furthermore, an insulation material which is different to that of the insulating matrix is selected for the insulation layer between the conductor track and the heat sink.

Therefore, in the case of the circuit support according to the invention, the at least one conductor track is encapsulated by injection molding with the first insulation material in such a way that the insulating matrix furthermore leaves open at least one second region which is arranged between the conductor track and the heat sink. A circuit support according to the invention furthermore includes a large number of spacers which are designed and arranged in order to set a height of the second region between the conductor track and the heat sink. In this case, a circuit support according to the invention furthermore includes a second insulation material which is different from the first insulation material of the insulating matrix and with which the second region is filled.

Accordingly, the insulating matrix, which is cost-effective in respect of material, is furthermore used for providing the required inherent rigidity and the electrical insulation of the top side of the conductor track. The material thickness of the insulating matrix, in particular on the at least one conductor track, is preferably between 0.2 mm and 0.4 mm. However, a second insulation material is used for the second region, for example a thermally conductive paste or a thermally conductive adhesive which, however, is expensive but has a thermal conductance which is several orders of magnitude better than the insulating matrix. However, since the thickness of the second region can be set to be extremely thin by means of the spacers, on the one hand the thermal resistance of this layer is very low but on the other hand the consumption of the second insulation material is likewise extremely low.

On account of the second region having a very low height, this moreover results in very good distribution of heat and a very short thermal conduction path. The thickness of the second region can be set very precisely owing to the use of the spacers. Since both the conductor track and also the heat sink are preferably metallic, the coefficients of thermal expansion of the materials which surround the second insulation material on opposite sides are very similar, and therefore the risk of the second insulation material being torn off owing to a shearing effect is virtually eliminated. The excellent heat transfer between the conductor track and the heat sink allows the conductor tracks to be short, that is to say the surface area required can be kept small, and results in a circuit support which takes up considerably less installation space than the concepts known from the prior art. This moreover results in possible savings in respect of price. As an alternative, electronic components with a considerably higher power loss, that is to say of higher power classes, can be operated with a circuit support according to the invention, on account of the higher thermal capacity, than would be the case in the prior art.

A circuit support according to the invention therefore provides more reliable electrical insulation by means of spacers, an increased heat dissipation capacity as a result of better distribution of heat owing to thicker connection points, which are more advantageous for spreading heat, shorter thermal conduction paths, fewer material transitions, larger cross sections, contacts with a larger surface area by means of the layer of the second insulation material, which layer can be homogeneously achieved with a greater thickness than before and is therefore easier to process, to the heat sink, that is to say in particular to the heat sink which can be electrically conductive, in particular composed of aluminum, in a preferred embodiment but can also be composed of other materials and have different thicknesses and also can be designed to be electrically neutral. Considerable cost advantages over the prior art are produced as a result of the reduction in parts and processes.

In a preferred embodiment of a circuit support according to the invention, the at least one conductor track is in the form of a lead frame. Therefore, all of the advantages which are known in the field of lead frames can be implemented. As an alternative, the conductor track can also be designed with wiring.

The first insulation material preferably has a viscosity of at least 10¹⁸ Pa·s, in particular of at least 10²² Pa·s, in the end state, which constitutes the cured state here, in order to provide the circuit support with the required stability. The second insulation material preferably has a viscosity of at most 10¹⁶ Pa·s, in particular of at most 10¹⁴ Pa·s, in the end state, that is to say after the circuit support is complete. As is obvious to a person skilled in the art, the viscosity of the materials used changes over the course of the service life of the circuit support. Within the meaning of the present invention, “end state” means the time period between completion of the circuit support and the end of the useful service life under the given operating conditions here.

The first insulation material may be, for example, a plastic of the thermoplastic type, whereas the second insulation material may be, for example, a thermally conductive paste and/or a thermally conductive adhesive, for example phase change material and/or filled epoxides. The first insulation material can be selected, in particular, such that it exhibits low adhesion forces to the conductor track 22, in particular lower adhesion forces than the second insulation material. The first insulation material, which is used for the insulating matrix, can be provided to be, in particular, technologically thicker than the second insulation material. The first insulation material is furthermore selected such that it surrounds the circuit support with a friction fit and/or with a force fit.

In a further embodiment, the spacers are in the form of particles which are distributed in the second insulation material. The height of the second region is preferably between 20 μm and 200 μm, and for this reason said particles have a corresponding size.

The conductor track can preferably have passage openings, wherein the projections on that side of the conductor track which faces the heat sink, which projections are produced during overmolding of said passage openings with the first insulation material of the insulating matrix, constitute the spacers. Therefore, the height of the second region can be set in a particularly cost-effective manner since the particles for setting the height of the second region can be dispensed with.

A particularly preferred development is distinguished in that the circuit support furthermore includes fastening aids, in particular mounting and alignment aids, for the circuit support, which aids are formed from the material for the insulating matrix and/or from the material of the at least one conductor track, in particular latching lugs, centering openings, snap-action hooks, spacers, register marks, reinforcing ribs, measurement sensors and/or measuring points.

In a preferred embodiment, the voltage difference between the conductor track and the heat sink is 19 V. This defines the minimum height of the second region.

The preferred embodiments presented with respect to a circuit support according to the invention and the advantages of said embodiments correspondingly apply, if applicable, to the method according to the invention for manufacturing a circuit support for an electronic circuit.

In said method, at least one conductor track is first produced from a starting material by removing unnecessary material. The at least one conductor track is then encapsulated by injection molding using a first insulation material so as to form an insulating matrix, wherein the encapsulation by injection molding is performed in such a way that at least one first region of the at least one conductor track is left open for the connection of at least one electronic component of the electronic circuit. Moreover, a heat sink is provided. According to the invention, the step of encapsulation by injection molding is performed in such a way that the insulating matrix furthermore leaves open at least one second region which is arranged between the conductor track and the heat sink. The method furthermore includes the step of filling the second region with a second insulation material using spacers for setting a height of the second region between the conductor track and the heat sink.

The second insulation material can be distinguished by a high adhesion force in comparison to the heat sink 18 and/or the conductor track 22, in particular by a higher adhesion force than the first insulation material.

The heat sink can also be formed by a vehicle chassis.

The step of producing the at least one conductor track from a starting material is preferably performed with the removal of material, in particular by a jet of water or a laser, or without the removal of material, in particular by punching.

The invention furthermore relates to a light source, in particular to a light source for a vehicle lighting arrangement, preferably a vehicle headlamp, including a circuit support according to the invention.

Further preferred embodiments are apparent from the dependent claims.

Embodiments of the present invention will now be explained in greater detail in the text which follows with reference to the appended drawings, in which:

FIG. 1 is a schematic illustration of a cross section through a circuit support concept known from the prior art using a printed circuit board;

FIG. 2 is a schematic illustration of a cross section through a circuit support concept known from the prior art using a lead frame;

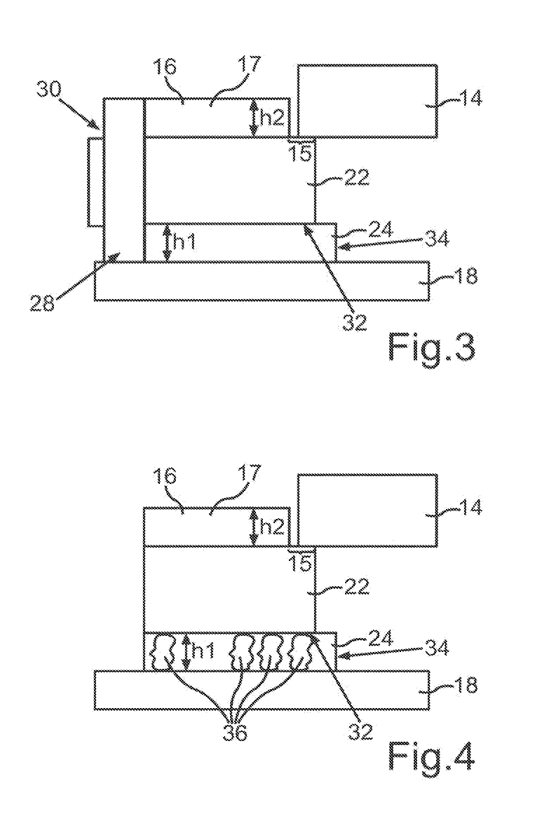

FIG. 3 is a schematic illustration of a cross section through a first embodiment of a circuit support according to the invention; and

FIG. 4 is a schematic illustration of a cross section through a second embodiment of a circuit support according to the invention.

FIG. 3 is a schematic illustration of a first embodiment of a circuit support according to the invention. Said circuit support has a conductor track 22 which is in the form of a lead frame in particular. Passage openings and/or gaps 30 are provided in the conductor track 22, said passage openings and/or gaps, when the conductor track is encapsulated by injection molding with a first insulation material 17 so as to form an insulating matrix 16, likewise being encapsulated by injection molding and in the process also forming a projection 28, in particular, on that side of the conductor track 22 which is intended to be coupled to a heat sink 18. This projection 28 can also extend beneath the conductor track 22 in order to ensure a better friction and/or force fit. During encapsulation by injection molding with the first insulation material 17, the region 15, which is provided for mounting the electronic components 14, and the region 34 on the bottom face 32 of the conductor track 22 are accordingly left open. This is performed by corresponding design of the injection molding mold.

A large number of projections 28 of this kind, which act as spacers, are produced by providing corresponding passage openings and/or gaps 30 along the conductor track 22, that is to say in the direction perpendicular to the plane of the drawing.

If a heat sink 18 is now placed onto the large number of projections 28, a region 34 which has a height h1 of between 20 μm and 200 μm is produced. In contrast, the height h2 of the matrix material 17 is between 0.2 mm and 0.4 mm. The region 34 is then filled with a second insulation material 24 which can constitute, in particular, a thermally conductive paste or a thermally conductive adhesive.

As an alternative, the second insulation material 24 can be introduced between the projections 28, in particular by being sprayed on and then withdrawn, before the heat sink is fitted. (The projections which have already cured define the remaining height of the insulation layer composed of the second insulation material 24, wherein the heat sink 18 is then fitted.)

The first insulation material 17, from which the matrix 16 is formed, preferably has a viscosity of at least 10¹⁸ Pa·s, in particular of at least 10²² Pa·s, in the end state, which constitutes the cured state here, in order to provide the circuit support with the necessary stability. The second insulation material 24 preferably has a viscosity of at most 10¹⁶ Pa·s, in particular of at most 10¹⁴ Pa·s, in the end state, that is to say after the circuit support is complete.

Only a portion of the respective electrical contact of the electrical components 14 to the conductor track is shown in the illustration of FIG. 3. The exit point has not been shown on account of the mirror-image symmetry.

In the embodiment illustrated in FIG. 4, particles 36 are provided in the second insulation material 24 instead of the projections 28 which are formed by encapsulation of the passage openings and/or gaps 30 by injection molding, the diameter of said particles defining the height h1 of the insulation layer which is formed from the second insulation material 24. Particles 36 of this kind are formed, in particular, from hexagonal boron nitride-coated silver spheres.

In preferred embodiments, the second insulation material 24 cures a lot more slowly than the first insulation material 17.

1. A circuit support for an electronic circuit, comprising:
at least one conductor track;
a first insulation material with which the at least one conductor track is encapsulated by injection molding so as to form an insulating matrix and so as to leave open at least one first region for the connection of at least one electronic component of the electronic circuit; and a heat sink;
wherein the at least one conductor track is encapsulated by injection molding with the first insulation material in such a way that the insulating matrix furthermore leaves open at least one second region which is arranged between the conductor track and the heat sink,
wherein the circuit support further comprises a large number of spacers which are designed and arranged in order to set a height of the second region between the conductor track and the heat sink,
wherein the circuit support further comprises a second insulation material with which the second region is filled.

2. The circuit support as claimed in claim 1,
wherein the at least one conductor track is in the form of a lead frame.

3. The circuit support as claimed in either of claims 1 and 2 claim 1,
wherein the first insulation material has a higher viscosity in the end state than the second insulation material in the end state, wherein the first insulation material has a viscosity of at least 10¹⁸ Pa·s, in the end state, wherein the second insulation material has a viscosity of at most 10¹⁶ Pa·s, in the end state.

4. The circuit support as claimed in claim 1,
wherein the first insulation material is different from the second insulation material, or the first insulation material is identical to the second insulation material.

5. The circuit support as claimed in claim 3,
wherein the spacers are in the form of particles which are distributed in the second insulation material.

6. The circuit support as claimed in claim 1,
wherein the height of the second region is from 20 μm to 200 μm.

7. The circuit support as claimed in claim 1,
wherein the conductor track has passage openings, wherein projections on that side of the conductor track which faces the heat sink, which projections are produced during overmolding of said passage openings with the material of the insulating matrix, constitute the spacers.

8. The circuit support as claimed in claim 1,
wherein the circuit support further comprises fastening aids, in particular for the circuit support, which aids are formed from the first insulation material and/or from the material of the at least one conductor track.

9. The circuit support as claimed in claim 1,
wherein the heat sink is electrically conductive.

10. The circuit support as claimed in claim 1,
wherein the material thickness of the insulating matrix is between 0.2 mm and 0.4 mm.

11. A method for manufacturing a circuit support for an electronic circuit, the method comprising:
producing at least one conductor track from a starting material by removing unnecessary material;
encapsulating the at least one conductor track by injection molding using a first insulation material so as to form an insulating matrix, wherein the encapsulation by injection molding is performed in such a way that at least one first region of the at least one conductor track is left open for the connection of at least one electronic component of the electronic circuit; and
providing a heat sink;
wherein the encapsulating is performed in such a way that the insulating matrix furthermore leaves open at least one second region which is arranged between the conductor track and the heat sink;
wherein the method further comprises:
filling the second region with a second insulation material using spacers for setting a height of the second region between the conductor track and the heat sink.

12. The method as claimed in claim 11,
wherein in producing the at least one conductor track, the conductor track is produced with the removal of material or without the removal of material.

13. A light source comprising a circuit support,
the circuit support comprising:
at least one conductor track;
a first insulation material with which the at least one conductor track is encapsulated by injection molding so as to form an insulating matrix and so as to leave open at least one first region for the connection of at least one electronic component of the electronic circuit and
a heat sink;
wherein the at least one conductor track is encapsulated by injection molding with the first insulation material in such a way that the insulating matrix furthermore leaves open at least one second region which is arranged between the conductor track and the heat sink,
wherein the circuit support further comprises a large number of spacers which are designed and arranged in order to set a height of the second region between the conductor track and the heat sink,
wherein the circuit support further comprises a second insulation material with which the second region is filled.

14. The circuit support as claimed in claim 3,
wherein the first insulation material has a viscosity of at least 10²² Pa·s, in the end state, wherein the second insulation material has a viscosity of at most 10¹⁴ Pa·s, in the end state.

15. The circuit support as claimed in claim 8,
wherein the circuit support further comprises mounting and alignment aids.

16. The circuit support as claimed in claim 8,
wherein the fastening aids are formed from latching lugs, centering openings, snap-action hooks, spacers, register marks, reinforcing ribs, measurement sensors and/or measuring points.

17. The circuit support as claimed in claim 10,
wherein the material thickness of the insulating matrix on the at least one conductor track is between 0.2 mm and 0.4 mm.

18. The method as claimed in claim 12,
wherein the conductor track is produced by a jet of water or a laser, or by punching.

19. The light source according to claim 13,
wherein the light source is used for a vehicle headlamp.
